(19) United States
(12) Patent Application Publication
(10) Pub. No.: US 2003/0127707 A1
(43) Pub. Date: Jul. 10, 2003

(54) BIPOLAR TRANSISTOR AND METHOD OF MANUFACTURING THE SAME

(75) Inventors: Mr. Masashi Matsushita, Kyoto (JP); Mr. Takayuki Kito, Kyoto (JP)

(73) Assignee: Rohm Co., Ltd., Kyoto, 615-8585 (JP)

(21) Appl. No.: 10/248,321

(22) Filed: Jan. 9, 2003

(30) Foreign Application Priority Data
Jan. 9, 2002 (JP) 2002-002164
Jan. 9, 2002 (JP) 2002-002165

(51) Int. Cl. H01L 27/082

(52) U.S. Cl. 257/573

(57) ABSTRACT

### Abstract of Disclosure

A discrete bipolar transistor for use in high frequency circuits is disclosed, in which a base electrode is formed in a base region through contact holes formed in a thermal oxide film without forming a CVD oxide film on the thermal oxide film, and an emitter contact layer composed of polysilicon and an emitter electrode are formed on an emitter region. The wide diffusion of dopant that occurs during CVD oxide film annealing can be prevented, and a shallow base region can be formed.

### Background of Invention

1. Field of the Invention

This invention generally relates to a bipolar transistor, and in particular to a bipolar transistor employed in a high frequency circuit.

2. Background Information

As shown in Fig. 37, a bipolar transistor employed in a high frequency circuit is comprised of an n-type semiconductor substrate 10, a collector region 20 that is comprised of an n-type epitaxial layer formed on top of the semiconductor substrate 10, a base region 30 comprised of a p⁺ diffusion layer formed on the surface of the collector region 20, an emitter layer 40 comprised of an n diffusion layer formed on the surface of the base region 30, and a thermal oxide film 50 and a CVD oxide film 60 that are formed on the surfaces of the base region 30 and the emitter region 40 such that they expose a portion of each of these regions. A base diffusion region 31 is formed in the base region 30, and is comprised of a p⁺ diffusion layer which reduces contact resistance. A base electrode 82 is formed on the surface of the base diffusion region 31. In addition, an emitter contact layer 71 is connected to the emitter region 40, and is comprised of a polysilicon layer that is electrically connected therewith. An emitter electrode 81 is formed on the emitter contact layer 71, and a collector electrode 100 is formed on the bottom surface of the n-type semiconductor substrate 10 and electrically connected therewith.

With this type of bipolar transistor, the surface of an n-type epitaxial layer is thermally oxidized to form the thermal oxide film 50. The base diffusion region 31 is formed by implanting a high concentration of a p-type dopant through the thermal oxide film 50 into the position where the base electrode 82 of the collector region 20 is to be formed. In addition, the base region 30 is formed by implanting the entire surface of the collector region 20 with a p-type dopant. Next, the CVD oxide film 60 is formed on top of the thermal oxide film 50, and a contact hole 91 is formed in the position where the emitter region 40 of the thermal oxide film 50 and the CVD oxide film 60 is to be located. A contact layer comprising polysilicon is formed on top of the CVD oxide film 60. The emitter region 40 is then formed by implanting the base region 30 with an n type dopant from the top of the contact layer through the contact hole 91. Next, the emitter contact layer 71 is formed by patterning the contact layer. In addition, a contact hole 92 is formed where the base diffusion region 31 of the thermal oxide film 50 and the CVD oxide film 60 is located, and the emitter electrode 81 and the base electrode 82 are formed by forming and patterning an Al or AlSi layer. A collector electrode 100 is formed on the bottom surface of the n-type semiconductor substrate 10.

Forming the CVD oxide film 60 on top of the thermal oxide film 50 serves to prevent the thermal oxide film 50 from being removed during etching, and the base region 30 and the emitter region 40 from being exposed, when the Al or AlSi layer is etched.

However, the CVD oxide film 60 is formed by annealing an oxide film laminated thereon by CVD. Because of that, the dopant in the base region 30 becomes deeply diffused, and the base region 30 becomes thicker. If the base region 30 becomes thicker, it becomes difficult for the carriers to move from the emitter region 40 to the collector region 20, thus making it difficult to drive the bipolar transistor at a high frequency.

On the other hand, if the annealing time is reduced in order to prevent the dopant from becoming deeply diffused, the CVD oxide film 60 will contract, the base electrode 82 or the emitter contact layer 71 formed on top of the CVD oxide film 60 will be stressed and will peel away therefrom, and contact resistance will increase. Moreover, if the base electrode 82 peels away from the CVD oxide film 60, etching gas will enter into this space when the Al or AlSi is etched and the base electrode 82 is formed, and will completely remove the base electrode 82. In addition, if the emitter contact layer 71 and the emitter electrode 81 peel away from the CVD oxide film 60, etching gas will enter into this space when the Al or AlSi is etched and the emitter electrode 81 is formed, and will completely remove the emitter electrode 81.

Furthermore, in order to insure that the emitter contact layer 71 is only formed below the emitter electrode 81, separate masks will need to be used to etch the contact layer and the Al or AlSi layer.

In addition, an alignment margin is needed for the emitter contact layer 71 and the emitter electrode 81, the distance between the emitter electrode 81 and the base electrode 82 will lengthen, the resistance between both regions will increase, and improvement in the high frequency characteristics of the circuit will be hindered.

### Summary of Invention

Thus, it is an object of the present invention to form a thin base region in a bipolar transistor employed in a high frequency circuit, and thereby improve the high frequency characteristics of the bipolar transistor.

It is also an object of the present invention to simplify the process of manufacturing bipolar transistors.

In a first aspect of the present invention, a bipolar transistor is formed on top of a semiconductor substrate, and comprised of a first region of a first conductivity type formed on top of the semiconductor substrate, a second region of a second conductivity type formed on a surface of the first region, a third region of the first conductivity type formed on a surface of the second region, a thermal oxide film having a first hole therein that exposes the third region and a second hole therein that exposes the second region, a first electrode that applies a voltage to the third region through the first hole, a first contact layer of the first conductivity type formed in between the first electrode and the third region, a second electrode that applies a voltage to the second region through the second hole, and a third electrode that applies a voltage to the first region.

In the first aspect of the present invention, only a thermal oxide film is formed on top of the second and third regions, and a CVD oxide film is not formed on top of the thermal oxide film. It is not necessary to oxidize a CVD film and anneal the CVD oxide film. Thus, the dopant inside the second region can be prevented from diffusing to a deep position during annealing, and the second region (base region) can be prevented from becoming thick. As a result, the high frequency characteristics of the bipolar transistor will improve, thus allowing them to be employed in VCOs (voltage control oscillators) and tuner circuits used in devices such as portable telephones and the like that are driven at high frequencies.

In a second aspect of the present invention, the third electrode is formed on the bottom surface of the semiconductor substrate. This configuration allows an increase in the bipolar transistor packaging density.

In a third aspect of the present invention, a third hole is formed in the thermal oxide film that exposes the first region, thereby allowing the third electrode to apply a voltage to the first region through the third hole.

Because the third electrode applies a voltage through the third hole, it can apply a voltage from the surface of the semiconductor substrate. Thus, wires are not needed when using face down packaging.

In a fourth aspect of the present invention, a second contact layer of the second conductivity type is formed in between the second electrode and the second region.

The process of manufacturing the bipolar transistor of the present invention will be simplified by forming contact layers between the first electrode and the third region and the second electrode and the second region, and by forming the first and second contact layers to have the same pattern as the first and second electrodes.

In a fifth aspect of the present invention, a third contact layer of the first conductivity type is formed in between the third electrode and the first region.

Like with the fourth aspect of the present invention, the process of manufacturing the bipolar transistor of the present invention will be simplified by forming contact layers between the first electrode and the third region, the second electrode and the second region, and the third electrode and the first region, and by forming the first, second, and third contact layers to have the same pattern as the first, second and third electrodes.

In a sixth aspect of the present invention, the thermal oxide film is formed to have an active region that is thinner than any other region thereof.

For example, a pad electrode having a large surface area is formed outside the active region and serves to relay signals to the first and second electrodes. By forming a thick thermal oxide film outside the active region, the capacitance due to the pad electrode formed outside the active region will be reduced, thus preventing the high frequency characteristics of the bipolar transistor from worsening.

In a seventh aspect of the present invention, a method of manufacturing a bipolar transistor on top of a semiconductor substrate comprises the steps of forming a first region of a first conductivity type on top of the semiconductor substrate, forming a second region of a second conductivity type on a surface of the first region, forming a third region of the first conductivity type on a surface of the second region, forming a thermal oxide film on top of the first, second and third regions, forming a first hole in the thermal oxide film that exposes the third region and forming a second hole in the thermal oxide film that exposes the second region, forming a first contact layer of the first conductivity type in the third region through the first hole, forming a first electrode that applies a voltage to the third region on the surface of the first contact layer, forming a second electrode that applies a voltage to the first region through the second hole, and forming a third electrode that applies a voltage to the third region.

In this manufacturing method, a thermal oxide film is formed only on top of the second and third regions, and a CVD oxide film is not formed on top of the thermal oxide film. It is therefore not necessary to anneal the CVD oxide film, and the dopant inside the second region can be prevented from diffusing to a deep position, and the second region (base region) can be prevented from becoming thick. As a result, the high frequency characteristics of the bipolar transistor will improve, thus allowing them to be employed in VCOs (voltage control oscillators) and tuner circuits used in devices such as portable telephones and the like that are driven at high frequencies.

In an eighth aspect of the present invention, the third electrode is formed on the bottom surface of the semiconductor substrate during the third electrode formation step in the bipolar transistor manufacturing method according to the seventh aspect of the present invention. This configuration allows an increase in the bipolar transistor packaging density.

In a ninth aspect of the present invention, the hole formation step of the bipolar transistor manufacturing method according to the seventh aspect of the present invention further includes the step of forming a third hole in the thermal oxide film that exposes the first region, and in the third electrode formation step, the third electrode is formed to be in electrical contact with the first region through the third hole.

Because the third electrode applies a voltage through the third hole, it can apply a voltage from the surface of the semiconductor substrate. Thus, wires are not needed when using face down packaging.

In a tenth aspect of the present invention, the thermal oxide film formed during the thermal oxide formation step of the bipolar transistor manufacturing method according to the seventh aspect of the present invention has an active region that is thinner than any other region thereof.

For example, a pad electrode having a large surface area is formed outside the active region and serves to relay signals to the first and second electrodes. By forming a thick thermal oxide film outside the active region, the capacitance due to the pad electrode formed outside the active region will be reduced, thus preventing the high frequency characteristics of the bipolar transistor from worsening.

In an eleventh aspect of the present invention, the first and second electrodes formed during the first and second electrode formation steps of the bipolar transistor manufacturing method according to the seventh aspect of the present invention are composed of Al or AlSi.

In a twelfth aspect of the present invention, the steps of forming the first and second electrodes from Al or AlSi in the bipolar transistor manufacturing method according to the eleventh aspect of the present invention are comprised of an electrode layer etching step in which the Al or AlSi is etched with a mixed gas composed of 20 to 40 wt% of BCl₃, SiCl₄, or BBr₃ added to Cl₂ as an additive gas and the selection ratio between the Al and a resist film is 1.5 to 2.5, and after this step is complete, a residue removal step in which Al or AlSi residue is stripped off with a mixed gas composed of 5 to 20 wt% of BCl₃, SiCl₄, or BBr₃ added to Cl₂ as an additive gas, the selection ratio between the Al or AlSi and a resist film is 2 to 3, and the selection ration between the Al or Si and the thermal oxide film is 20 to 100.

Thus, the first and second electrodes can be formed with almost no damage to the thermal oxide film, even if no CVD oxide film is formed on top of the thermal oxide film, by dividing the Al or AlSi etching into two steps, i.e., a main etching step (electrode layer etching step) and an over etching step (residue removal step).

In a thirteenth aspect of the present invention, a method of manufacturing a bipolar transistor on top of a semiconductor substrate comprises the steps of forming a first region of a first conductivity type on top of the semiconductor substrate, forming a second region of a second conductivity type on a surface of the first region, forming a third region of the first conductivity type on a surface of the second region, forming a thermal oxide film on top of the first, second and third regions, forming a first hole in the thermal oxide film that exposes the third region and forming a second hole in the thermal oxide film that exposes the second region, and after forming the first and second holes in the thermal oxide film, sequentially forming a contact layer and an electrode layer, etching the electrode layer to form a first electrode in the first hole and a second electrode in the second hole, using the first and second electrode as a mask and etching the contact layer, and forming a third electrode that applies a voltage to the first region.

After etching the electrode layer and forming the first and second electrodes, the number of etching masks can be reduced by using the first and second electrodes as a mask and etching the contact layer. In addition, because the first and second electrodes are used as a mask when etching the contact layer, the contact layer below the first and second electrodes is self aligning, thereby eliminating the need for an alignment margin. Thus, the distance between the first and second electrodes can be reduced, the resistance between the first and second electrodes can be reduced, and the high frequency characteristics of the bipolar transistor can be improved.

In a fourteenth aspect of the present invention, the third electrode is formed on the bottom surface of the semiconductor substrate during the third electrode formation step in the bipolar transistor manufacturing method according to the thirteenth aspect of the present invention. This configuration allows an increase in the bipolar transistor packaging density.

In a fifteenth aspect of the present invention, the hole formation step in the bipolar transistor manufacturing method according to the thirteenth aspect of the present invention further includes the step of forming a third hole in the thermal oxide film that exposes the first region, and in the third electrode formation step, forming the third electrode to be in electrical contact with the first region through the third hole.

Because the third electrode applies a voltage through the third hole, it can apply a voltage from the surface of the semiconductor substrate. Thus, wires are not needed when using face down packaging.

In a sixteenth aspect of the present invention, the second region formation step in the bipolar transistor manufacturing method according to the thirteenth aspect of the present invention further comprises a first implantation step which includes implanting dopant of the second conductivity type from above the thermal oxide film into the first region, and a second implantation step which includes implanting dopant of the second conductivity type from above the contact layer into the same position in which the dopant of the first implantation step was implanted into the first region.

By implanting dopant not only from above the thermal oxide film but also from above the contact layer, the high density diffusion region formed in the second region will draw near the third region, the resistance between the first and second electrodes can be further reduced, and the high frequency characteristics of the bipolar transistor can be improved.

In a seventeenth aspect of the present invention, the thermal oxide film formed in the thermal oxide film formation step of the bipolar transistor manufacturing method according to the thirteenth aspect of the present invention has an active region that is thinner than any other region thereof.

For example, a pad electrode having a large surface area is formed outside the active region and serves to relay signals to the first and second electrodes. By forming a thick thermal oxide film outside the active region, the capacitance due to the pad electrode formed outside the active region will be reduced, thus preventing the high frequency characteristics of the bipolar transistor from worsening.

In an eighteenth aspect of the present invention, the first and second electrodes formed during the electrode formation step of the bipolar transistor manufacturing method according to the thirteenth aspect of the present invention are composed of Al or AlSi.

These and other objects, features, aspects and advantages of the present invention will become apparent to those skilled in the art from the following detailed description, which, taken in conjunction with the annexed drawings, discloses preferred embodiments of the present invention.

### Brief Description of Drawings

Referring now to the attached drawings which form a part of this original disclosure:

Fig. 1 is a cross-section of a bipolar transistor according to a first embodiment of the present invention;

Fig. 2 shows a step in a method of manufacturing the bipolar transistor according to the first embodiment of the present invention;

Fig. 3 shows a step in a method of manufacturing the bipolar transistor according to the first embodiment of the present invention;

Fig. 4 shows a step in a method of manufacturing the bipolar transistor according to the first embodiment of the present invention;

Fig. 5 shows a step in a method of manufacturing the bipolar transistor according to the first embodiment of the present invention;

Fig. 6 shows a step in a method of manufacturing the bipolar transistor according to the first embodiment of the present invention;

Fig. 7 shows a step in a method of manufacturing the bipolar transistor according to the first embodiment of the present invention;

Fig. 8 shows the conditions used in a step etching method used to manufacture the bipolar transistor according to the first and a third embodiment of the present invention;

Fig. 9 is a cross-section of a bipolar transistor according to a second embodiment of the present invention;

Fig. 10 shows a step in a method of manufacturing the bipolar transistor according to the second embodiment of the present invention;

Fig. 11 shows a step in a method of manufacturing the bipolar transistor according to the second embodiment of the present invention;

Fig. 12 shows a step in a method of manufacturing the bipolar transistor according to the second embodiment of the present invention;

Fig. 13 shows a step in a method of manufacturing the bipolar transistor according to the second embodiment of the present invention;

Fig. 14 shows a step in a method of manufacturing the bipolar transistor according to the second embodiment of the present invention;

Fig. 15 shows a step in a method of manufacturing the bipolar transistor according to the second embodiment of the present invention;

Fig. 16 shows a step in a method of manufacturing the bipolar transistor according to the second embodiment of the present invention;

Fig. 17 shows a step in a method of manufacturing the bipolar transistor according to the second embodiment of the present invention;

Fig. 18 shows a step in a method of manufacturing the bipolar transistor according to the second embodiment of the present invention;

Fig. 19a is a first plan view of a bipolar transistor according to a third and fourth embodiment of the present invention;

Fig. 19b is a second plan view of the bipolar transistor according to the third and fourth embodiment of the present invention;

Fig. 19c is a cross-section of Fig. 19a taken along line A-A';

Fig. 20 is a cross-section of the bipolar transistor according to the third embodiment of the present invention;

Fig. 21 shows a step in a method of manufacturing the bipolar transistor according to the third embodiment of the present invention;

Fig. 22 shows a step in a method of manufacturing the bipolar transistor according to the third embodiment of the present invention;

Fig. 23 shows a step in a method of manufacturing the bipolar transistor according to the third embodiment of the present invention;

Fig. 24 shows a step in a method of manufacturing the bipolar transistor according to the third embodiment of the present invention;

Fig. 25 shows a step in a method of manufacturing the bipolar transistor according to the third embodiment of the present invention;

Fig. 26 shows a step in a method of manufacturing the bipolar transistor according to the third embodiment of the present invention;

Fig. 27 is a cross-section of the bipolar transistor according to a fourth embodiment of the present invention;

Fig. 28 shows a step in a method of manufacturing the bipolar transistor according to the fourth embodiment of the present invention;

Fig. 29 shows a step in a method of manufacturing the bipolar transistor according to the fourth embodiment of the present invention;

Fig. 30 shows a step in a method of manufacturing the bipolar transistor according to the fourth embodiment of the present invention;

Fig. 31 shows a step in a method of manufacturing the bipolar transistor according to the fourth embodiment of the present invention;

Fig. 32 shows a step in a method of manufacturing the bipolar transistor according to the fourth embodiment of the present invention;

Fig. 33 shows a step in a method of manufacturing the bipolar transistor according to the fourth embodiment of the present invention;

Fig. 34 shows a step in a method of manufacturing the bipolar transistor according to the fourth embodiment of the present invention;

Fig. 35 shows a step in a method of manufacturing the bipolar transistor according to the fourth embodiment of the present invention;

Fig. 36 shows a step in a method of manufacturing the bipolar transistor according to the fourth embodiment of the present invention; and

Fig. 37 is a cross-section of a conventional bipolar transistor.

### Detailed Description

1. First Embodiment

A. Structure

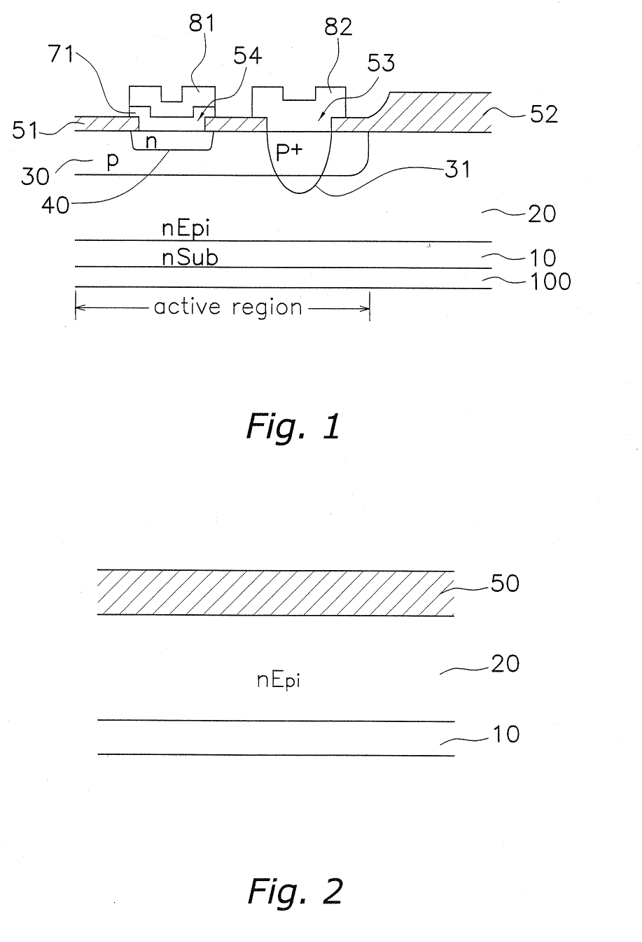

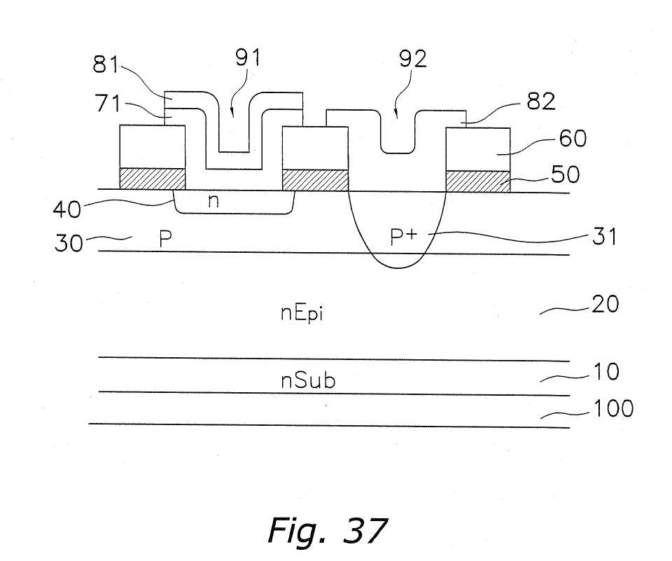

Fig. 1 is a cross-section of a bipolar transistor according to a first embodiment of the present invention. For the sake of simplicity, the same reference numerals used to describe the conventional bipolar transistor in Fig. 37 will be used in Figs. 1 to 8 when describing the same structures.

This bipolar transistor is comprised of an n-type semiconductor substrate 10, a collector region 20 that is formed on top of the n-type semiconductor substrate 10, a base region 30 that is formed inside the collector region 20, an emitter region 40 that is formed inside the base region 30, thermal oxide films 51, 52 that are formed on the surface of the base region 30 and the emitter region 40 and which include contact holes 53, 54, a base electrode 82 formed on top of the base region 30 through the contact hole 53, an emitter contact layer 71 composed of polysilicon and formed on top of the emitter region 40 through the contact hole 54, and an emitter electrode 81 that is formed on top of the emitter contact layer 71. Here, the thermal oxide films 51, 52 are an active thermal oxide film 51 that is formed in an active region that is made up of the collector, base, and emitter of the bipolar transistor, and a field thermal oxide film 52 that is formed in a field region outside the active region. In addition, a collector electrode 100 is formed on the bottom surface of the n-type semiconductor substrate 10 such that it is electrically connected therewith.

In the present embodiment, a CVD oxide film is not formed on top of the active oxide film 51. Thus, the dopant inside the base region 30 can be prevented from deeply diffusing into the collector region 20 when the CVD oxide film is annealed, and the base region 30 can be shallowly formed. As a result, the base region 30 can be made thinner, the carriers can move more easily from the emitter region 40 to the collector region 20, and the bipolar transistor can be driven at a high frequency. In addition, in the present embodiment, the field thermal oxide film 52 is formed such that it is thicker than the active thermal oxide film 51. Specifically, the film thickness of the active thermal oxide film 51 is 500 to 1000 angstroms, while the film thickness of the field thermal oxide film 52 is 500 to 10000 angstroms. Normally, a pad electrode for relaying signals to the base electrode 82 and the emitter electrode 81 is formed over a large area other than the active region. However, the capacitance of the pad electrode can be prevented from becoming too large by forming a thick field thermal oxide film 52 below the pad electrode.

B. Manufacturing process

The manufacturing process for the bipolar transistor according to the first embodiment of the present invention will be described below with reference to Figs. 2 through 8.

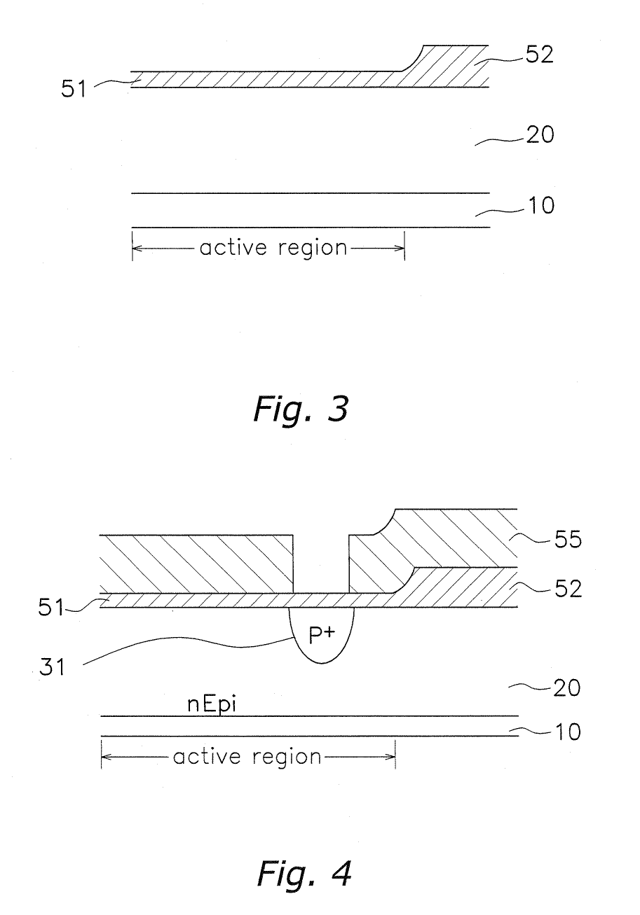

First, as shown in Fig. 2, an n-type epitaxial layer that will become the collector region 20 is formed on top of the n-type semiconductor substrate 10, and the thermal oxide film 50 is formed on top of the collector region 20 by thermally oxidizing the surface thereof. Next, as shown in Fig. 3, the portion of the thermal oxide film 50 that will become the active region of the bipolar transistor is etched, and the active thermal oxide film 51 and the field thermal oxide film 52 are formed.

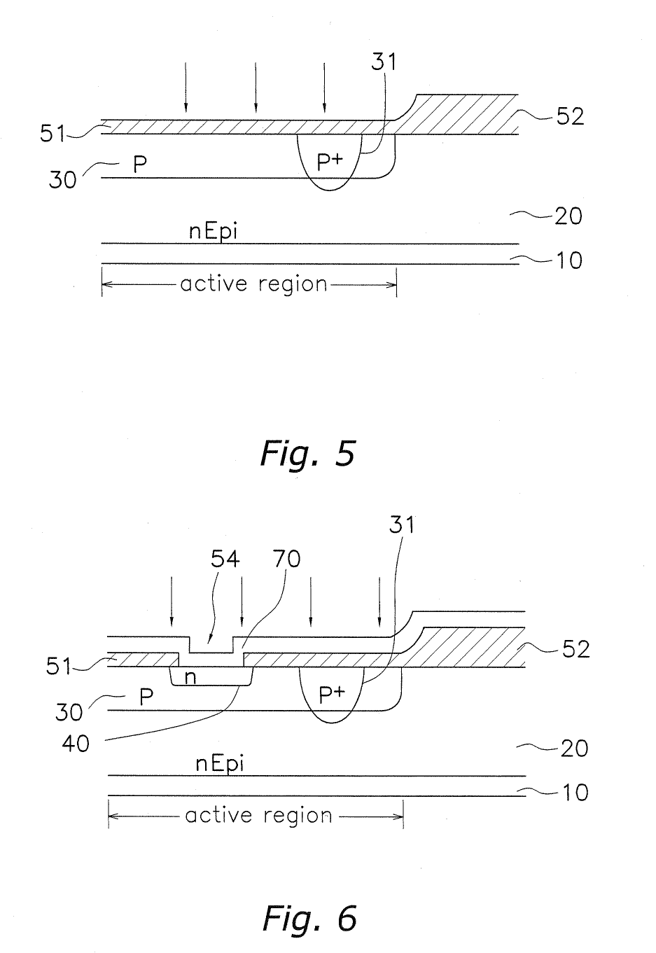

Next, as shown in Fig. 4, a resist pattern 55 is formed on top of the thermal oxide films 51, 52 such that a portion of the active thermal oxide film 51 is exposed, and this exposed region is implanted with boron ions at a density of 1 x 10¹⁹ to 5 x 10²⁰ atoms/cm³. Next, as shown in Fig. 5, after the resist pattern 55 is stripped off, the entire active thermal oxide film 51 is shallowly implanted with boron ions at a density of 5 x 10¹⁶ to 5 x 10¹⁷ atoms/cm³. The boron ions are then activated by annealing this region, thus forming the p⁺ base diffusion region 31 and the base region 30.

Next, as shown in Fig. 6, the active thermal oxide film 51 is etched, a contact hole 54 is formed, and a contact layer 70 comprised of polysilicon is formed on top of the thermal oxide films 51, 52. Next, arsenic or phosphorus ions are implanted from the top of the contact layer 70 and annealed, and then the arsenic or phosphorus ions are activated to form the emitter region 40.

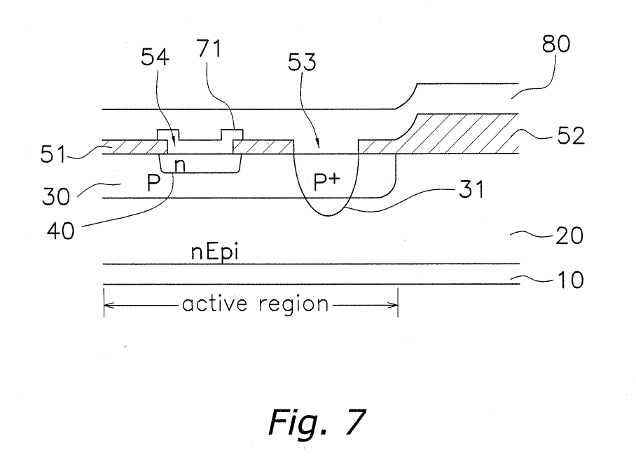

Next, as shown in Fig. 7, the contact layer 70 is etched and an emitter contact layer 71 is formed only on top of the emitter region 40. A contact hole 53 is then formed in the active thermal oxide film 51, and a metal layer 80 comprised of Al or AlSi over the thermal oxide films 51, 52, base diffusion region 31, and emitter region 40. Then, after a resist pattern is formed on top of the metal layer 80 and is etched, the base electrode 82 and emitter electrode 81 are formed in the positions shown in Fig. 1.

C. Electrode etching

The etching rate and selection ratio during the etching of the Al or AlSi metal layer 80 are changed by means of a step etching process that includes a start etching step, a main etching step, and an over etching step. The etching of the metal layer 80 by means of this step etching process is described below.

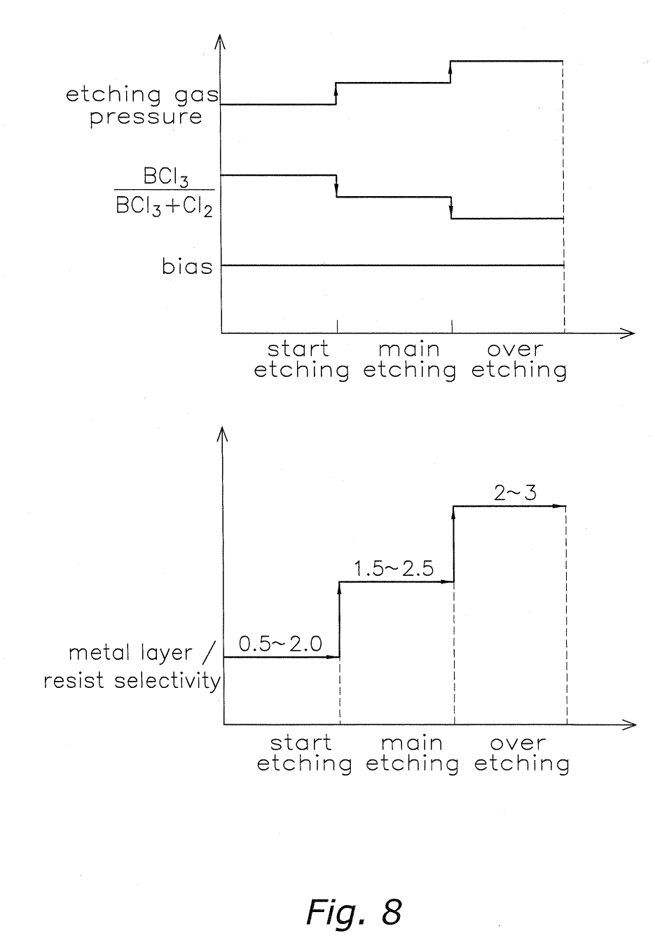

The parameters that will determine the etching rate and selection ratio of the metal layer 80 with respect to the resist film and the thermal oxide films 51, 52 are the gas pressure inside the chamber, the percentage of additive gas, and the bias voltage. The changes in these parameters during each step of the process are shown in Fig. 8. As shown therein, during the main etching step, the etching gas pressure is higher than the start etching step, the additive gas BCl₃ is reduced, and thus the selection ratio of the metal layer 80 with respect to the resist film will be larger. In the over etching step, the pressure inside the chamber is even higher and the additive gas BCl₃ is reduced, thereby maintaining the selection ratio of the metal layer 80 with respect to the resist film at the same level while increasing the selection ratio of the metal layer 80 with respect to the thermal oxide films 51, 52. Thus, damage to the thermal oxide films 51, 52 can be suppressed, and the metal layer 80 can be etched.

First, an etching gas comprised of a mixed gas of BCl₃ and Cl₂is introduced into the chamber at a base pressure of 5 to 20 mm Torr, and the pressure inside the chamber is adjusted to 10 to 40 mm Torr. At this time, no bias voltage is being applied. Note also that a etching gas comprised of a mixed gas of SiCl₄ and Cl₂ or BBr₃ and Cl₂ can also be employed.

Next, the native oxide Al₂O₃film that has formed on the surface of the metal layer 80 is etched in the start etching step. In this step, the amount of the additive gas BCl₃ is increased and the pressure thereof is lowered in order to increase the sputter etching rate. Thus, the Cl ions that are injected into the chamber at a right angle will have a greater impact, the physical reaction thereof will be stronger, and the Al₂O₃ will be etched by means of the sputtering effect. Specifically, the pressure in the chamber will be maintained at 10 to 40 mm Torr, the percentage of BCl₃ in the etching gas will be 40 to 90 wt%, and the bias voltage will be set to 50 to 300W. At this time, the selection ratio of the metal layer 80 with respect to the resist film will be adjusted to 0.5 to 2. Note also that when using an etching gas comprised of SiCl₄ and Cl₂ or BBr₃ and Cl₂, the percentage of SiCl₄ or BBr₃ in the gas will be adjusted to 40 to 90 wt%.

Next, the metal layer 80 is etched in the main etching step. In this step, there is less additive gas BCl₃ than in the start etching step, and thus the etching rate of the Al or AlSi will increase. In addition, the pressure inside the chamber will be higher than during the start etching step, and the selection ratio of the metal layer 80 with respect to the thermal oxide films 51, 52 will be increased. Specifically, the bias voltage will be maintained at 50 to 300 W, the pressure will be increased to 40 to 100 mm Torr, and the ratio of BCl₃ used in the etching gas will be reduced to 20 to 40 wt%, thereby adjusting the selection ratio of the metal layer 80 with respect to the resist film to 1.5 to 2.5. The point at which the etching of the metal layer 80 is complete can be detected by using a photoelectric detection means such as a photomultiplier tube or the like.

After the completion of the etching of the metal layer 80 has been detected, additional etching will be performed in the over etching step, and any remaining Al or AlSi residue will be removed. In this step as well, the selection ratio of the metal layer 80 with respect to the thermal oxide films 51, 52 will be increased so as to not etch the thermal oxide films 51, 52 below the emitter contact layer 71. In addition, the amount of BCl₃ gas used in the additive gas is reduced and the partial pressure thereof is lowered, and thus the ions other than the Cl ions that are injected into the chamber at a right angle will have a lower impact and the sputtering effect will be weakened. Specifically, the pressure inside the chamber is increased to 100 to 200 mm Torr, the percentage of BCl₃ is lowered to 5 to 20 wt%, the bias voltage is set to 40 to 300 W, the selection ratio of the metal layer 80 with respect to the resist film is adjusted to 2 to 3, and the selection ratio of the metal layer 80 with respect to the thermal oxide films 51, 52 is adjusted to 20 to 100. When over etching is performed for 0.5 to 1 minute under these conditions, 10 angstroms or less of the thermal oxide films 51, 52 will be removed.

Thus, a metal layer 80 comprised of Al or AlSi will be etched in the main etching step, and after the completion of the etching in this step is detected, the Al or AlSi residue can be reliably removed in the over etching step while only slightly etching the thermal oxide films 51, 52. This allows one to omit the step of forming a CVD oxide film in order to protect the thermal oxide films 51, 52.

D. Effects

In the bipolar transistor according to the present embodiment, a metal layer 80 comprised of Al or AlSi can be step etched, thus dramatically suppressing the amount of damage to the thermal oxide films 51, 52 below. Thus, it is not necessary to form a CVD oxide film in order to prevent damage to the thermal oxide films 51, 52.

Because the step of annealing the CVD oxide film has been eliminated, the deep diffusion of the dopant inside the base region 30 that occurs due to the heat used in annealing can be prevented, and it thus becomes possible to form a thin base region 30. It therefore becomes easier for the carriers to travel from the emitter region 40 to the collector region 20, and the bipolar transistor can thus be driven at a high frequency.

In addition, the field thermal oxide film 52 is formed to be thicker than the active thermal oxide film 52, and thus an increase in the capacitance of the pad electrode used for relaying signals from to the base electrode 82 and the emitter electrode 81 can be prevented.

Moreover, the packaging density of the bipolar transistor can be increased because the collector electrode 100 is formed on the bottom surface of the semiconductor substrate 10.

2. Second Embodiment

A. Structure

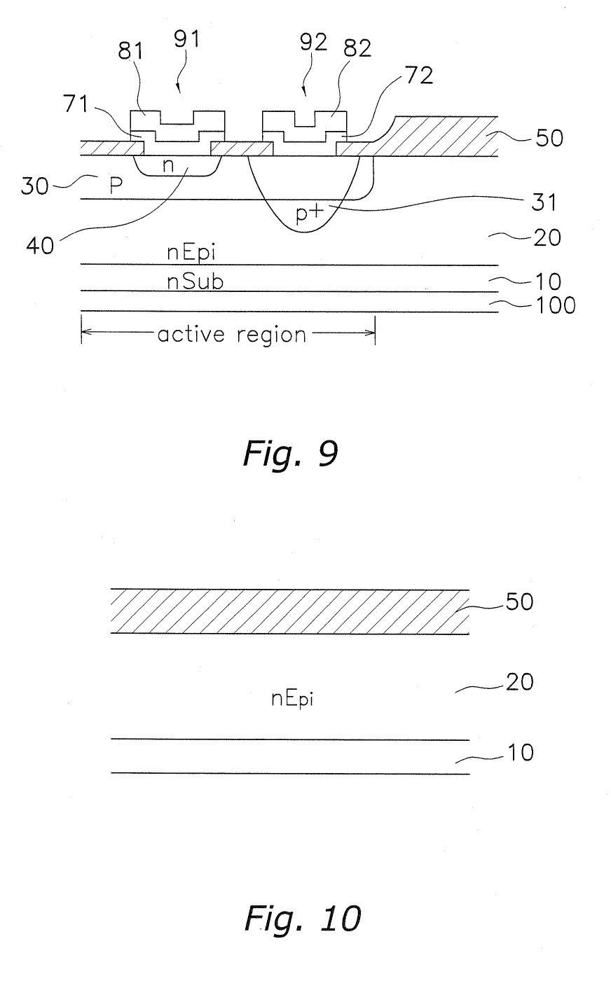

Fig. 9 is a cross-section of a bipolar transistor according to a second embodiment of the present invention. For the sake of simplicity, the same reference numerals used to describe the conventional bipolar transistor in Fig. 37 will be used in Figs. 9 to 16 when describing the same structures.

This bipolar transistor is comprised of an n-type semiconductor substrate 10, a collector region 20 that is formed on top of the n-type semiconductor substrate 10, a base region 30 that is formed on the surface of the collector region 20, a base diffusion region 31 that is formed such that it lies on top of the base region 30, and an emitter region 40 that is formed inside the base region 30. In addition, a thermal oxide film 50 is formed on the surface of the base diffusion region 31 and the emitter region 40, and contact holes 91 and 92 are formed through the thermal oxide film 50 over the points where the base diffusion region 31 and he emitter region 40 are located. An emitter contact layer 71 is formed through the contact hole 91, and an emitter electrode 81 is formed on the surface of the emitter contact layer 71. A base contact layer 72 is formed through the contact hole 92, and a base electrode 82 is formed on the surface of the base contact layer 72. In addition, a collector electrode 100 is formed on the bottom surface of the n-type semiconductor substrate 10.

B. Manufacturing process

The manufacturing process for the bipolar transistor according to the second embodiment of the present invention will be described below with reference to Figs. 10 through 16.

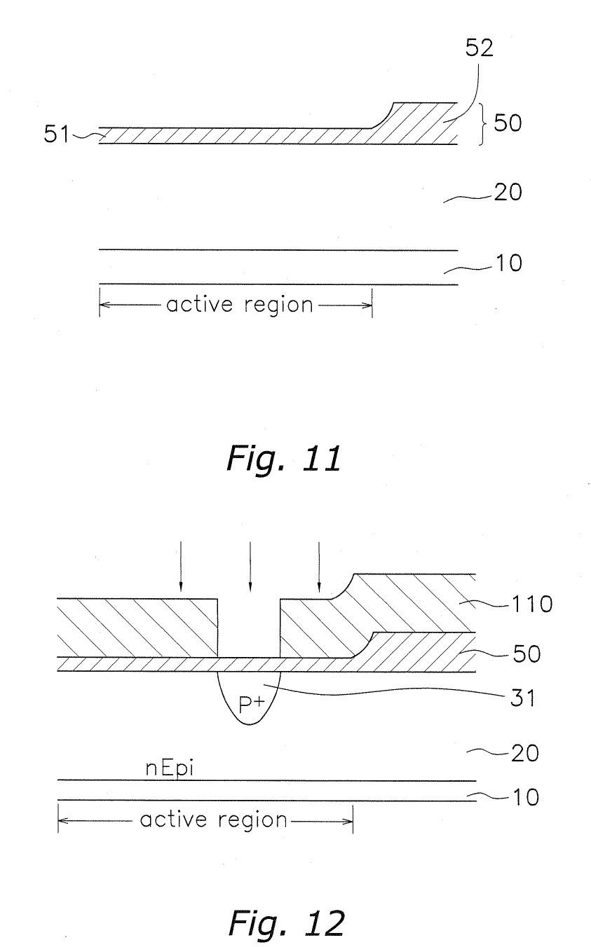

First, as shown in Fig. 10, an n-type epitaxial layer that will become the collector region 20 is formed on top of the n-type semiconductor substrate 10, and the thermal oxide film 50 is formed on top of the collector region 20 by thermally oxidizing the surface thereof. Next, as shown in Fig. 11, the portion of the thermal oxide film 50 that will become the active region of the bipolar transistor is etched, thereby forming a thin active thermal oxide film 51 and a field thermal oxide film 52.

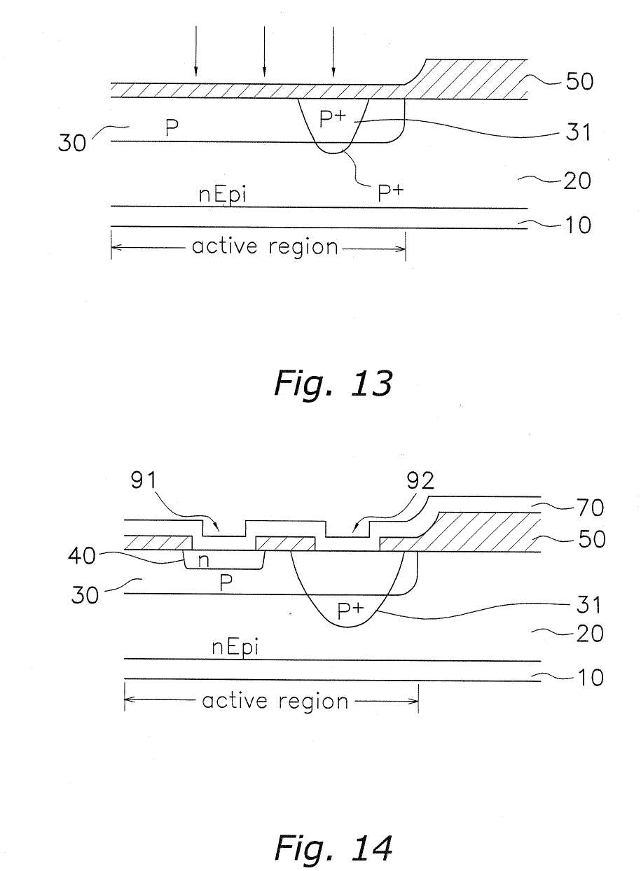

Next, as shown in Fig. 12, a resist pattern 110 is formed on top of the thermal oxide film 50 such that a portion of the thermal oxide film 50 is exposed, and this exposed region is implanted with boron ions at a density of 1 x 10¹⁹ to 5 x 10²⁰ atoms/cm³. As shown in Fig. 13, after the resist pattern 110 is stripped off, the entire thermal oxide film 50 is shallowly implanted with boron ions at a density of 5 x 10¹⁶ to 5 x 10¹⁷ atoms/cm³. The boron ions are then activated by annealing this region, thus forming the base diffusion region 31 and the base region 30.

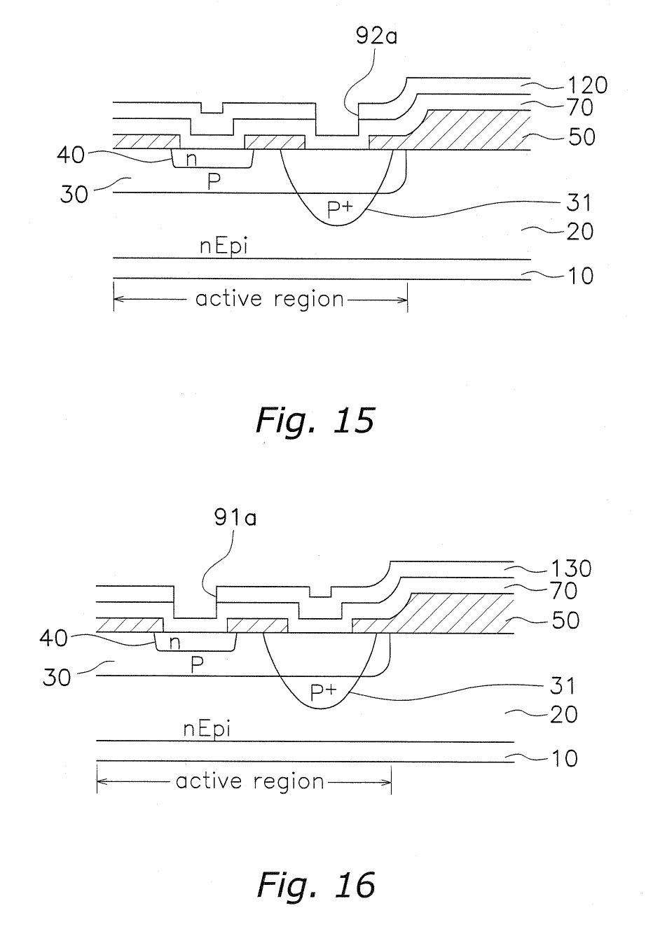

Next, as shown in Fig. 14, the thermal oxide film 50 (thermal oxide films 51, 52) is etched, the contact holes 91 and 92 are formed, and a contact layer 70 comprised of polysilicon is formed on top of the thermal oxide film 50. Next, as shown in Fig. 15, a resist pattern 120 is formed which has a hole 92a therein that is above the contact hole 92, and boron ions are implanted therein at a density of 1 x 10¹⁹ to 5 x 10²⁰ atoms/cm³. Next, as shown in Fig. 16, the resist pattern 120 is removed, a resist pattern 130 is formed which has a hole 91a therein that is above the contact hole 91, and arsenic or phosphorus ions are implanted therein at a density of 1 x 10¹⁹ to 5 x 10²⁰ atoms/cm³. The resist pattern 130 is then removed, and the base diffusion region 31 is enlarged and the emitter region 40 is formed by annealing this structure.

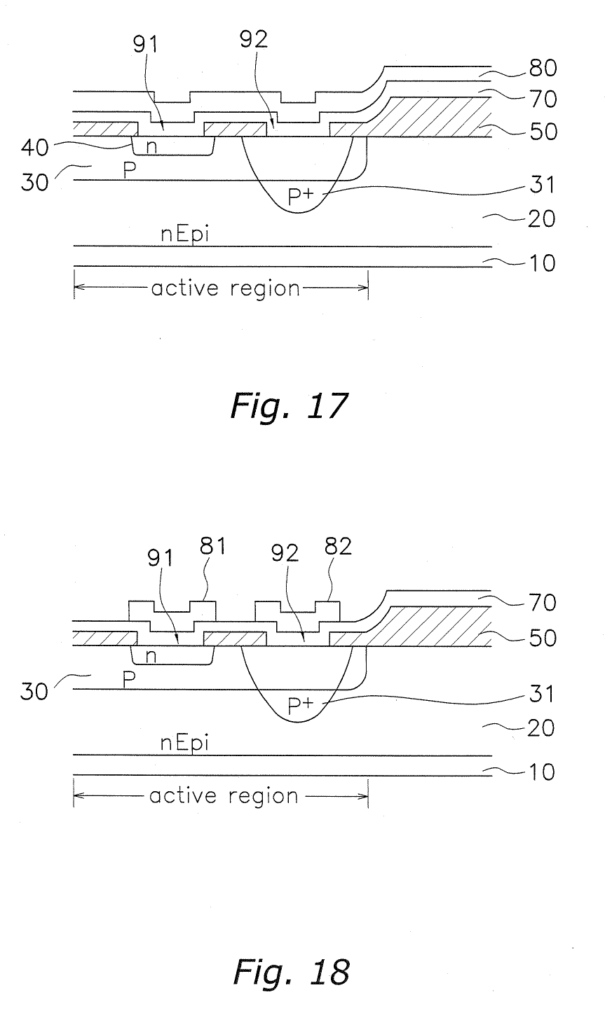

Next, as shown in Fig. 17, a metal layer 80 comprised of Al or AlSi is laminated thereon, and by etching the metal layer 80, the emitter electrode 81 and base electrode 82 are formed in the positions shown in Fig. 18. Furthermore, as shown in Fig. 9, by using the emitter electrode 81 and base electrode 82 as a mask and etching the contact layer 70, the emitter electrode 81 and base electrode 82 will have the same pattern as the emitter contact layer 71 and the base contact layer 72. Finally, the collector electrode 100 is formed on the bottom surface of the semiconductor substrate 10.

C. Effects

In the bipolar transistor according to the present embodiment, the masks needed for etching can be reduced because the emitter electrode 81 and base electrode 82 are used as masks during the etching of the contact layer 70.

In addition, the emitter electrode 81 and base electrode 82 and the emitter contact layer 71 and the base contact layer 72 can be self aligned because the emitter electrode 81 and base electrode 82 are used as masks, and because the emitter electrode 81 and base electrode 82 will have the same pattern as the emitter contact layer 71 and the base contact layer 72. Thus, an alignment margin is not needed, the distance between the emitter electrode 81 and base electrode 82 can be shortened in order to reduce the resistance between both electrodes, and the high frequency characteristics of the bipolar transistor can be improved.

In addition, the distance between the base diffusion region 31 and the emitter region 40 can be shortened because the p-type dopant is implanted at a high density from not only above the thermal oxide film 50 but also from above the contact layer 70. Thus, the resistance between the emitter electrode 81 and base electrode 82 can be reduced even further, and the high frequency characteristics of the bipolar transistor can be improved.

Moreover, because the step of annealing the CVD oxide film has been eliminated, the deep diffusion of the dopant inside the base region 30 that occurs due to the heat used in annealing can be prevented, and it thus becomes possible to form a thin base region 30. It therefore becomes easier for the carriers to travel from the emitter region 40 to the collector region 20, and the bipolar transistor can thus be driven at a high frequency.

Furthermore, the field thermal oxide film 52 is formed to be thicker than the active thermal oxide film 51, and thus an increase in the capacitance of the pad electrode used for relaying signals from to the base electrode 82 and the emitter electrode 81 can be prevented.

Moreover, the packaging density of the bipolar transistor can be increased because the collector electrode 100 is formed on the bottom surface of the semiconductor substrate 10.

3. Third Embodiment

A. Structure

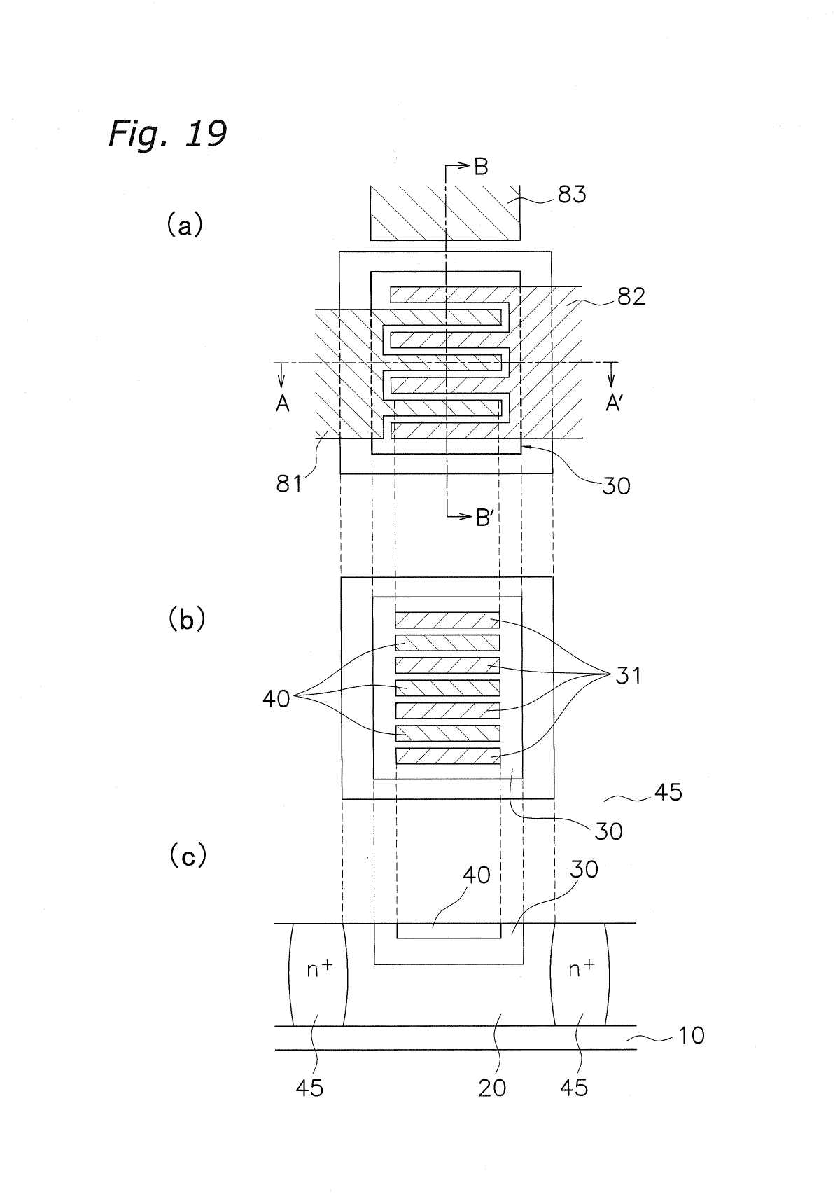

Fig. 19(a) is a plan view of a bipolar transistor according to a third embodiment of the present invention, Fig. 19(b) is a plan view of a diffusion region after the metal wiring shown in Fig. 19(a) is removed, and Fig. 19(c) is a cross-section of the interior of the semiconductor taken along the line A-A' in Fig. 19(a). For the sake of simplicity, the same reference numerals used to describe the bipolar transistor in the first embodiment will be used in Figs. 19 to 26 when describing the same structures.

As shown in Fig. 19(a), the bipolar transistor according to the third embodiment is formed such that the emitter electrode 81 and the emitter region 40, and the base electrode 82 and the base diffusion region 31, are sequentially disposed with respect to each other in a comb tooth like pattern. As shown in Fig. 19(c), collector wall regions 45 (n⁺ diffusion regions) are formed such that they surround the base region 30 and the emitter region 40. In addition, the collector wall regions 45 are connected to a collector electrode 83.

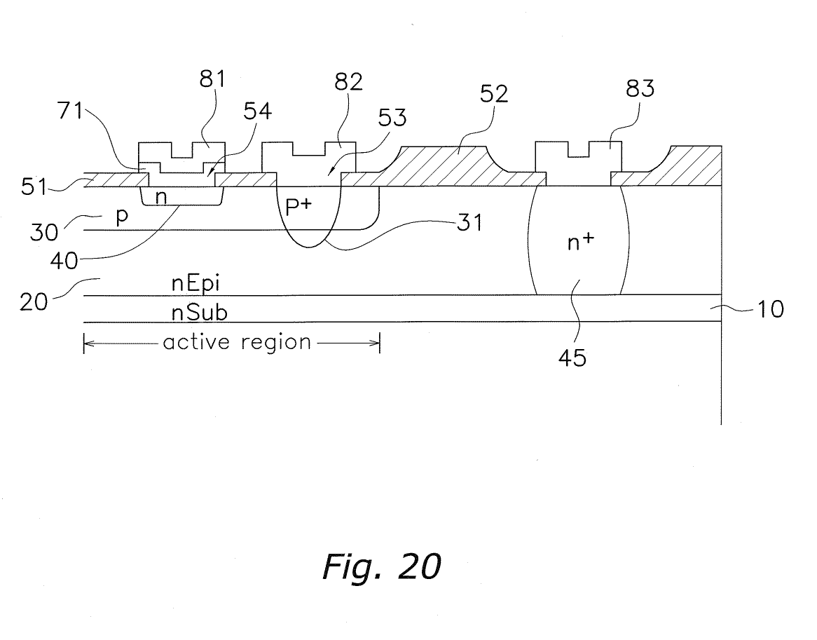

Fig. 20 is a cross-section of the essential portions of the semiconductor taken along the line B-B' of the plan view of the bipolar transistor according to the third embodiment shown in Fig. 19(a). In the bipolar transistor of the third embodiment shown in Fig. 20, a collector wall region 45 (n⁺ diffusion region) is formed inside the collector region 20 and extends up to the n-type semiconductor substrate 10. The collector electrode 83 is formed above the collector wall region 45. Thus, the structure of the bipolar transistor according to the third embodiment is identical with that of the first embodiment, except that the third embodiment includes the collector wall region 45, and the collector electrode 83 is formed on the surface of the collector region 20.

In the present embodiment, a CVD oxide film is not formed on top of the active oxide film 51. Thus, the dopant inside the base region 30 can be prevented from deeply diffusing into the collector region 20 when the CVD oxide film is annealed, and the base region 30 can be shallowly formed. As a result, the base region 30 can be made thinner, the carriers can move more easily from the emitter region 40 to the collector region 20, and the bipolar transistor can be driven at a high frequency. In addition, in the present embodiment, the field thermal oxide film 52 is formed such that it is thicker than the active thermal oxide film 51. Specifically, the film thickness of the active thermal oxide film 51 is 500 to 1000 angstroms, while the film thickness of the field thermal oxide film 52 is 5000 to 10000 angstroms. Normally, a pad electrode for relaying signals to the base electrode 82 and the emitter electrode 81 is formed over a large region other than the active region. However, the capacitance of the pad electrode can be prevented from becoming too large by forming a thick field thermal oxide film 52 below the pad electrode. Furthermore, a voltage can be applied from the surface of the semiconductor substrate 10 via the collector electrode 83 provided on the surface thereof because collector wall regions 45 are formed in the collector region 20. Thus, wires are not needed when using face down packaging.

In addition, the connection resistance from the bottom portion of the semiconductor substrate 10 to the surface thereof can be reduced by forming the collection wall regions 45.

B. Manufacturing process

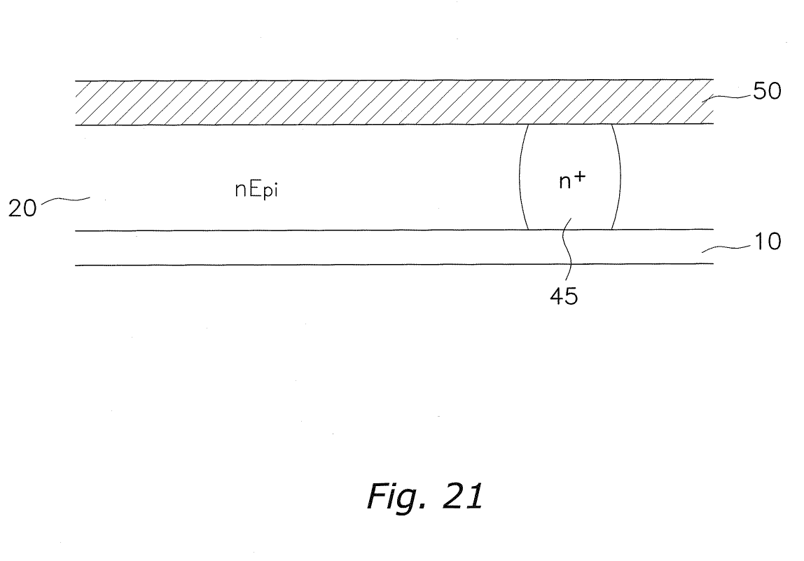

The manufacturing process for the bipolar transistor according to the third embodiment of the present invention will be described below with reference to Figs. 21 through 26.

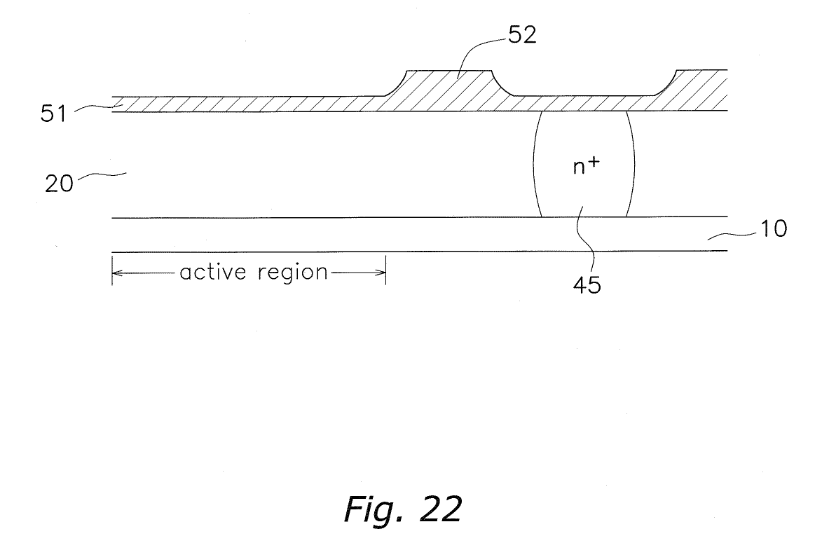

First, as shown in Fig. 21, an n-type epitaxial layer and a mask thermal oxide film are formed on top of the n-type semiconductor substrate 10, and the mask thermal oxide film over the portion of the n-type epitaxial layer that corresponds to a contact hole 93 is etched. Next, n-type dopant is implanted into a predetermined region of the n-type epitaxial layer via the hole in the mask thermal oxide film, and the collector wall 45 is formed by heat processing. Then, the entire surface of the mask thermal oxide film is etched and removed. The thermal oxide film 50 is then formed on the surface of the collector region 20 by thermally oxidizing this surface. Next, as shown in Fig. 22, the portion of the thermal oxide film 50 that will become the active region of the bipolar transistor is etched, thus forming the active thermal oxide film 51 and the field thermal oxide film 52.

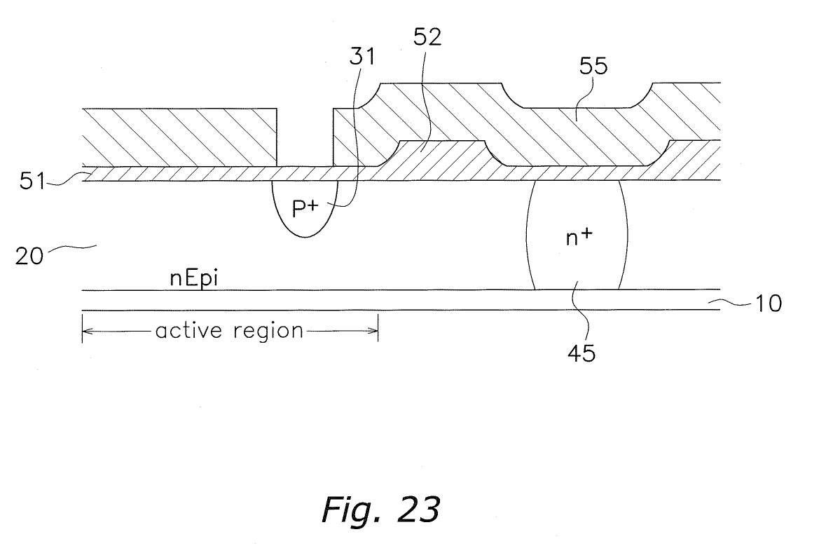

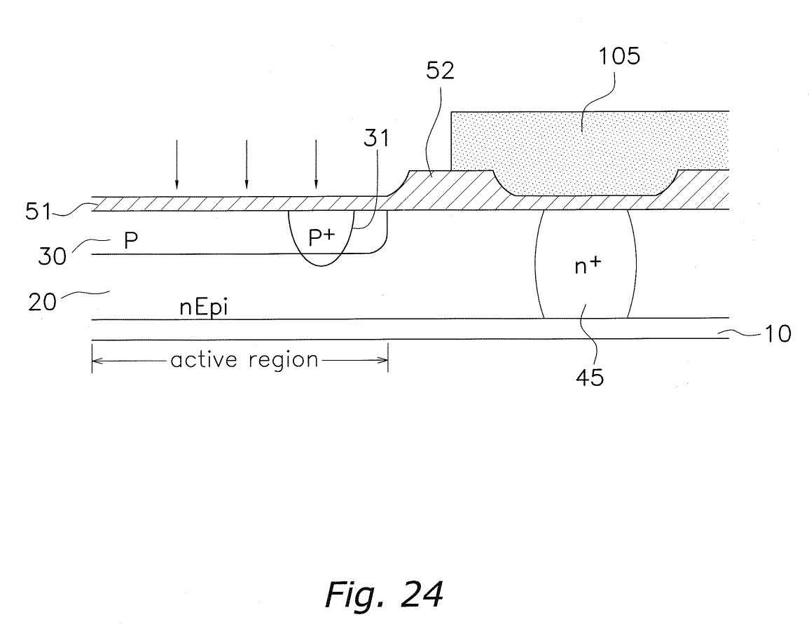

Next, as shown in Fig. 23, a resist pattern 55 is formed on top of the thermal oxide films 51, 52 such that a portion of the active thermal oxide film 51 is exposed, and this exposed region is implanted with boron ions at a density of 1 x 10¹⁹ to 5 x 10²⁰ atoms/cm³. Next, as shown in Fig. 24, after the resist pattern 55 is stripped off, a resist pattern 105 is formed on top of the collector wall region 45, and the entire active thermal oxide film 51 is shallowly implanted with boron ions at a density of 5 x 10¹⁶ to 5 x 10¹⁷ atoms/cm³. The boron ions are then activated by annealing this region, thus forming the p⁺ base diffusion region 31 and the base region 30.

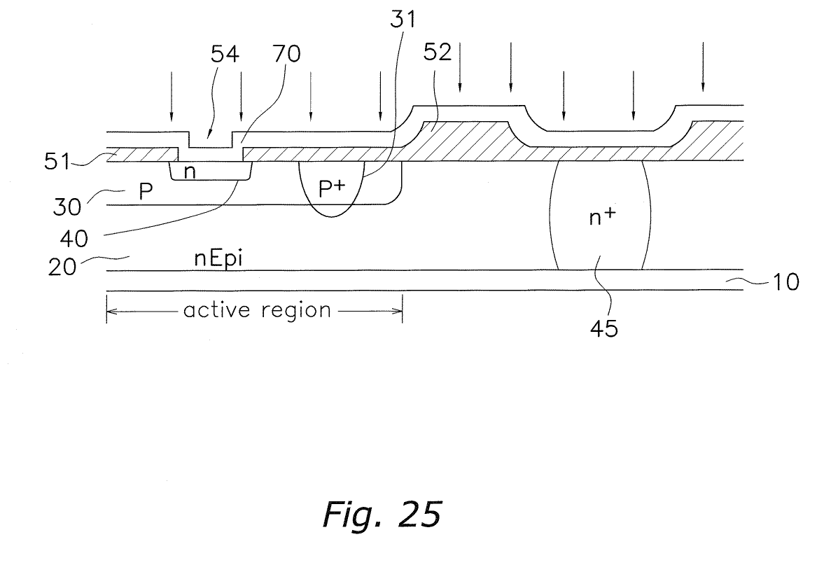

Next, as shown in Fig. 25, the active thermal oxide film 51 is etched, a contact hole 54 is formed, and a contact layer 70 comprised of polysilicon is formed on top of the thermal oxide films 51, 52. Next, arsenic or phosphorus ions are implanted from the top of the contact layer 70 and annealed, and then the arsenic or phosphorus ions are activated to form the emitter region 40.

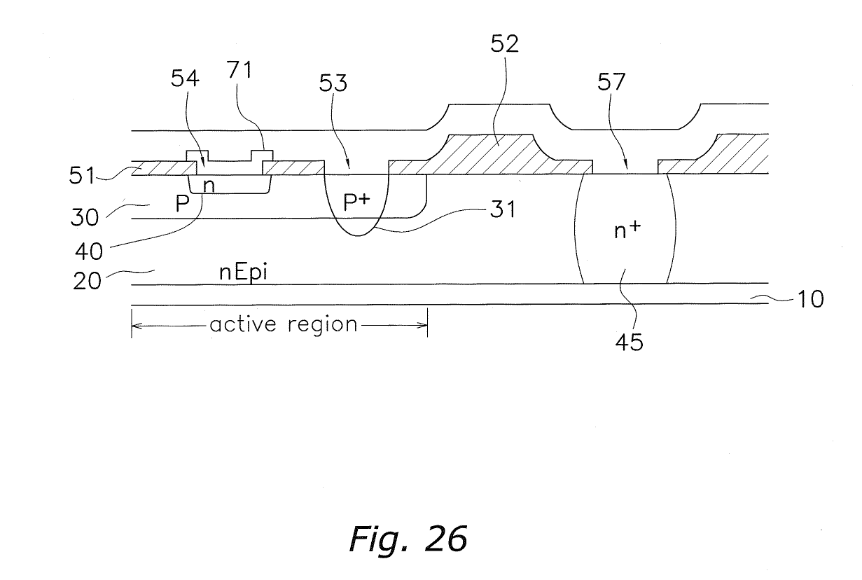

Next, as shown in Fig. 26, the contact layer 70 is etched and an emitter contact layer 71 is formed only on top of the emitter region 40. Contact holes 53, 57 are then formed in the active thermal oxide film 51, and a metal layer 80 comprised of Al or AlSi is formed on top thereof. Then, after a resist pattern is formed on top of the metal layer 80 and is etched, the base electrode 82, the emitter electrode 81, and the collector electrode 83 are formed in the positions shown in Fig. 20.

The process used for etching the electrodes is identical with that described in the first embodiment.

C. Effects

In the bipolar transistor according to the present embodiment, a metal layer 80 comprised of Al or AlSi can be step etched, thus dramatically suppressing the amount of damage to the thermal oxide films 51, 52 below. Thus, it is not necessary to form a CVD oxide film in order to prevent damage to the thermal oxide films 51, 52.

Because the step of annealing the CVD oxide film has been eliminated, the deep diffusion of the dopant inside the base region 30 that occurs due to the heat used in annealing can be prevented, and it thus becomes possible to form a thin base region 30. It therefore becomes easier for the carriers to travel from the emitter region 40 to the collector region 20, and the bipolar transistor can thus be driven at a high frequency.

In addition, the field thermal oxide film 52 is formed to be thicker than the active thermal oxide film 51, and thus an increase in the capacitance of the pad electrode used for relaying signals from to the base electrode 82 and the emitter electrode 81 can be prevented.

4. Fourth Embodiment

A. Structure

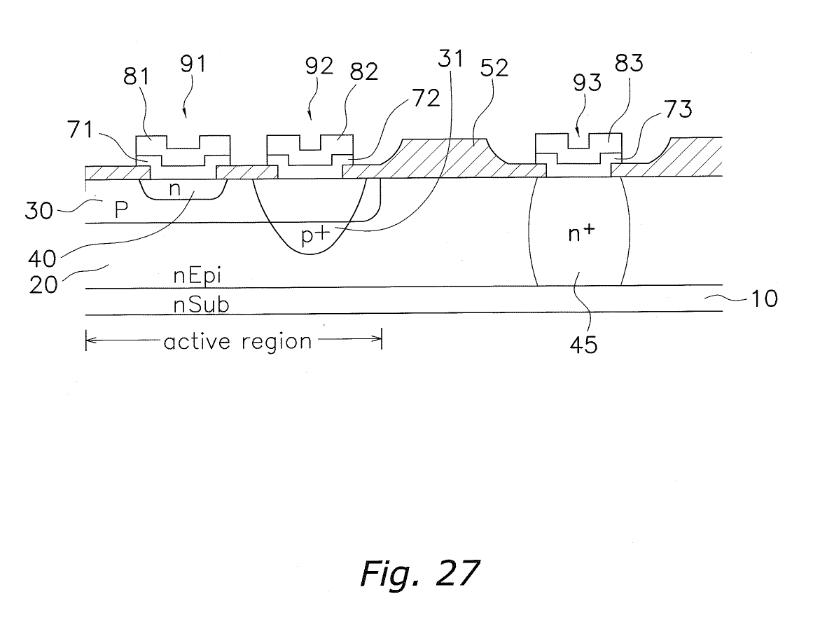

The cross-sectional and plan views in the fourth embodiment are identical with those shown in Fig. 19. Fig. 27 is a cross-section of the essential portions of the semiconductor taken along the line B-B' of the plan view of the bipolar transistor according to the third embodiment shown in Fig. 19(a). For the sake of simplicity, the same reference numerals used to describe the bipolar transistor in the second embodiment will be used in Figs. 27 to 36 when describing the same structures.

In the bipolar transistor of the fourth embodiment shown in Fig. 27, a collector wall region 45 (n⁺ diffusion region) is formed inside the collector region 20 and extends up to the n-type semiconductor substrate 10. A collector contact layer 73 is formed on top of the collector wall region 45 via the contact hole 93, and the collector electrode 83 is formed on the surface of the collector contact layer 73. Thus, in the bipolar transistor according to the fourth embodiment, the structure of the bipolar transistor is identical with that of the second embodiment, except that the fourth embodiment includes the collector wall region 45, and the collector electrode 83 and the collector contact layer 73 are formed on the surface of the semiconductor substrate 10.

B. Manufacturing process

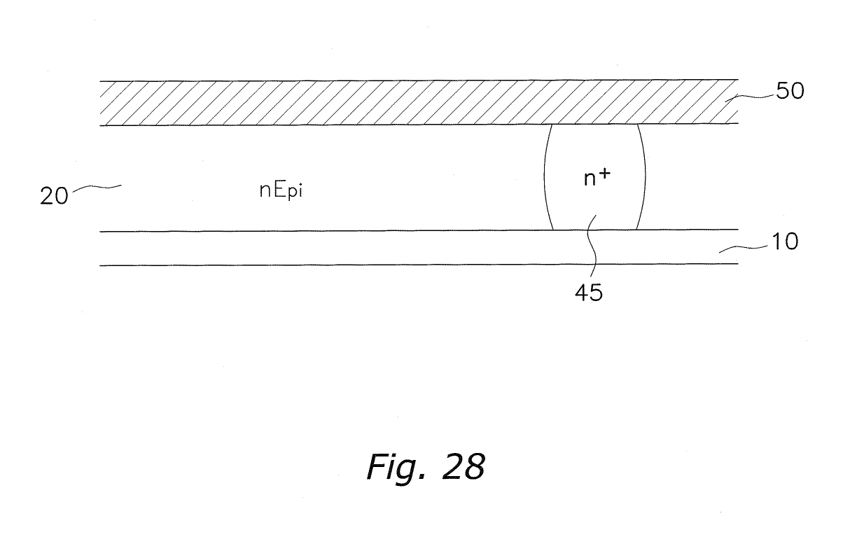

The manufacturing process for the bipolar transistor according to the fourth embodiment of the present invention will be described below with reference to Figs. 28 through 36.

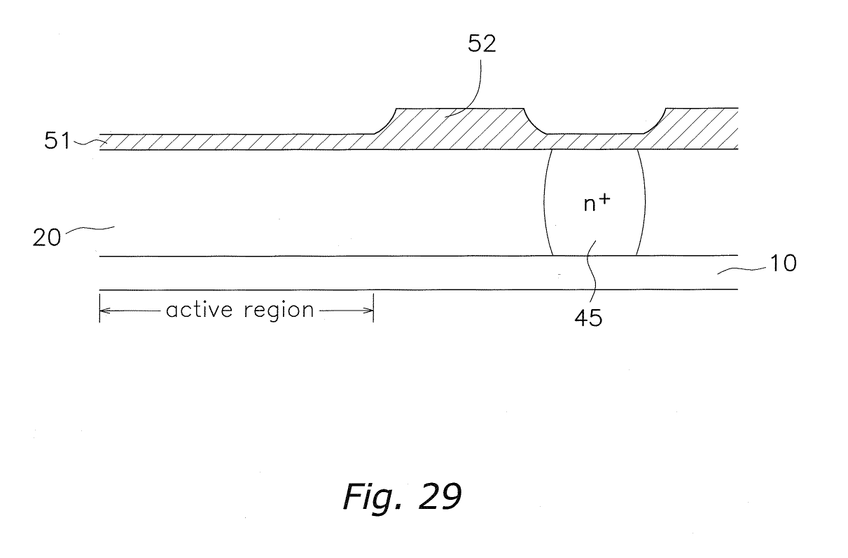

First, as shown in Fig. 28, an n-type epitaxial layer and a mask thermal oxide film are formed on top of the n-type semiconductor substrate 10, and the mask thermal oxide film over the portion of the n-type epitaxial layer that corresponds to a contact hole 93 is etched. Next, n-type dopant is implanted into a predetermined region of the n-type epitaxial layer via the hole in the mask thermal oxide film, and the collector wall 45 is formed by heat processing. Then, the entire surface of the mask thermal oxide film is etched and removed. The thermal oxide film 50 is then formed on the surface of the collector region 20 by thermally oxidizing this surface. Next, as shown in Fig. 29, the portion of the thermal oxide film 50 that will become the active region of the bipolar transistor is etched, thus forming the active thermal oxide film 51 and the field thermal oxide film 52.

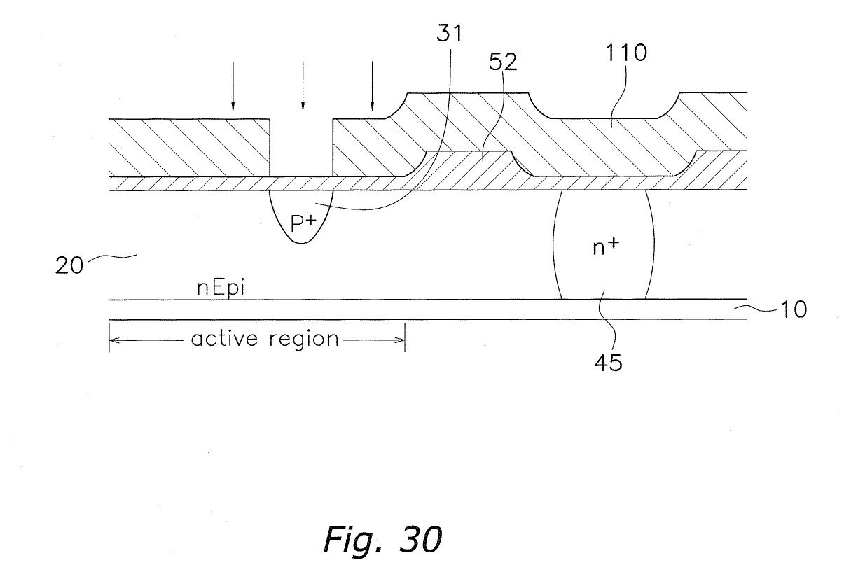

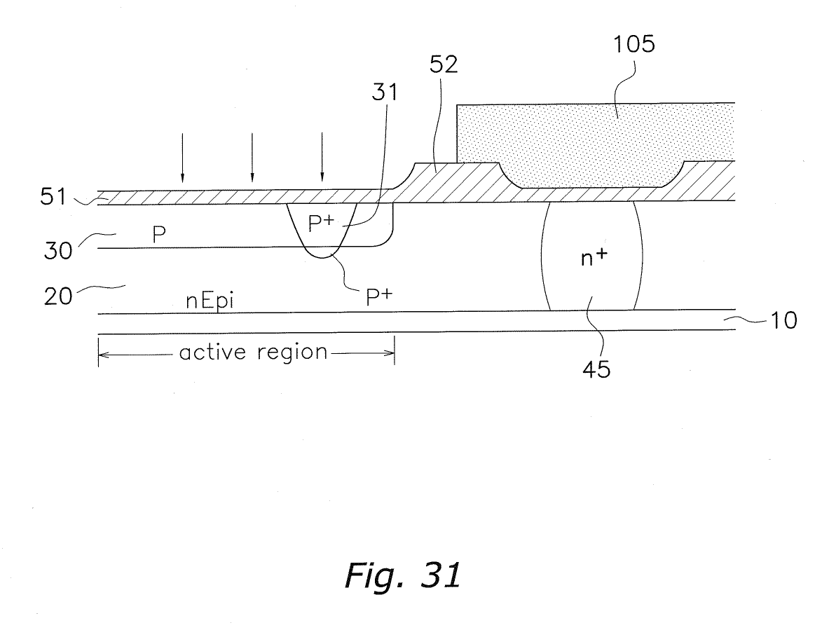

Next, as shown in Fig. 30, a resist pattern 110 is formed on top of the thermal oxide film 50 such that a portion thereof is exposed, and this exposed region is implanted with boron ions at a density of 1 x 10¹⁹ to 5 x 10²⁰ atoms/cm³. Next, as shown in Fig. 31, after the resist pattern 110 is stripped off, a resist pattern 105 is formed on top of the collector wall region 45, and the entire thermal oxide film 50 is shallowly implanted with boron ions at a density of 5 x 10¹⁶ to 5 x 10¹⁷ atoms/cm³. The boron ions are then activated by annealing this region, thus forming the p⁺ base diffusion region 31 and the base region 30.

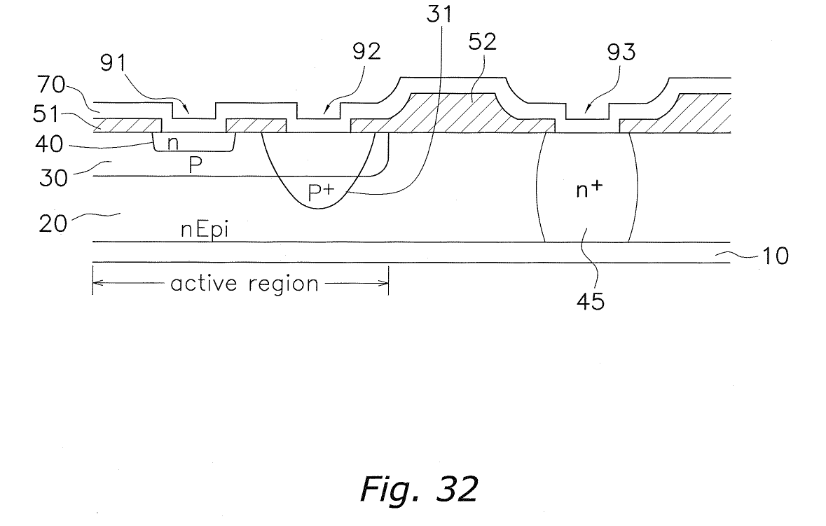

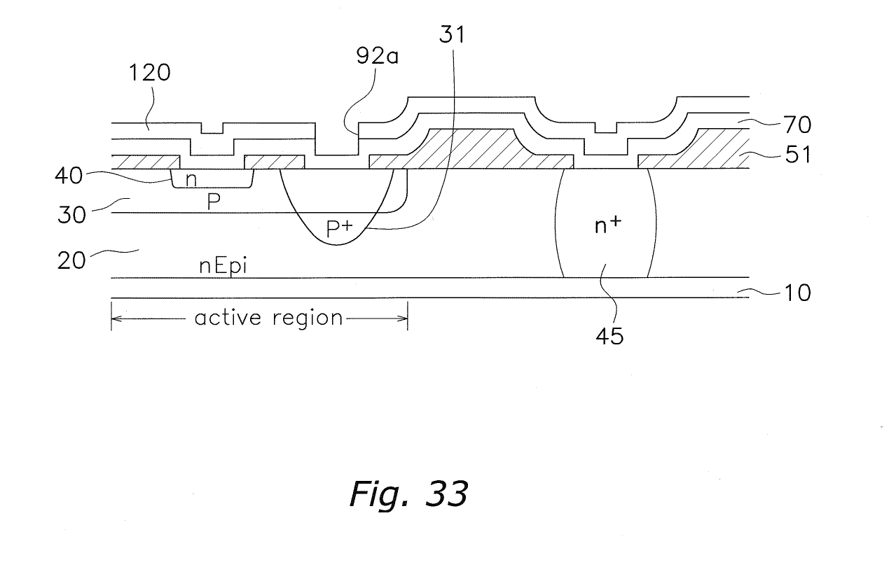

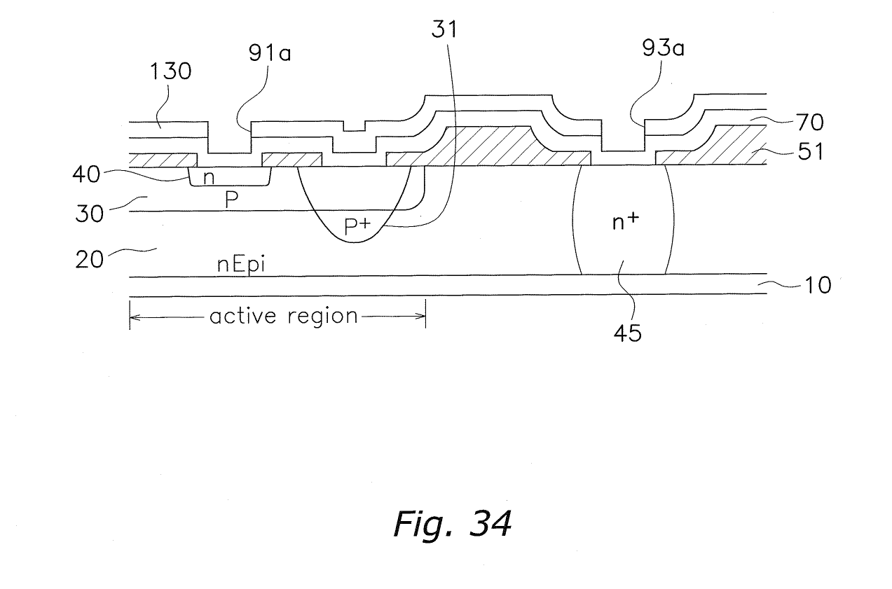

Next, as shown in Fig. 32, the thermal oxide film 50 (thermal oxide films 51, 52) is etched, contact holes 91, 92, and 93 are formed, and a contact layer 70 comprised of polysilicon is formed on top of the thermal oxide films 50. Next, as shown in Fig. 33, a resist pattern 120 is formed which has a hole 92a therein that is above the contact hole 92, and boron ions are implanted therein at a density of 1 x 10¹⁹ to 5 x 10²⁰ atoms/cm³. Next, as shown in Fig. 34, the resist pattern 120 is removed, a resist pattern 130 is formed which has holes 91a, 93a formed therein that are above the contact holes 91, 93, and arsenic or phosphorus ions are implanted therein at a density of 1 x 10¹⁹ to 5 x 10²⁰ atoms/cm³. The resist pattern 130 is then removed, and the base diffusion region 31 is enlarged and the emitter region 40 is formed by annealing this structure.

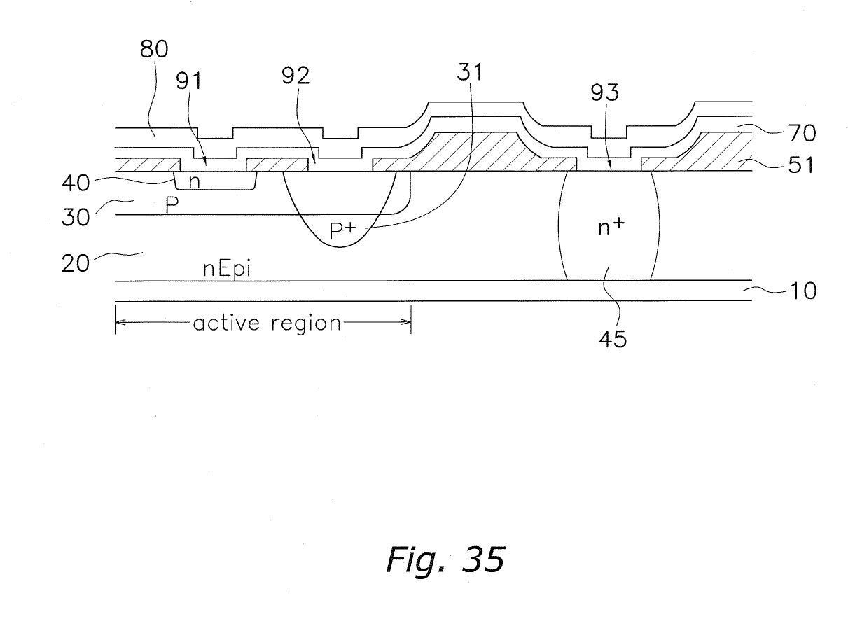

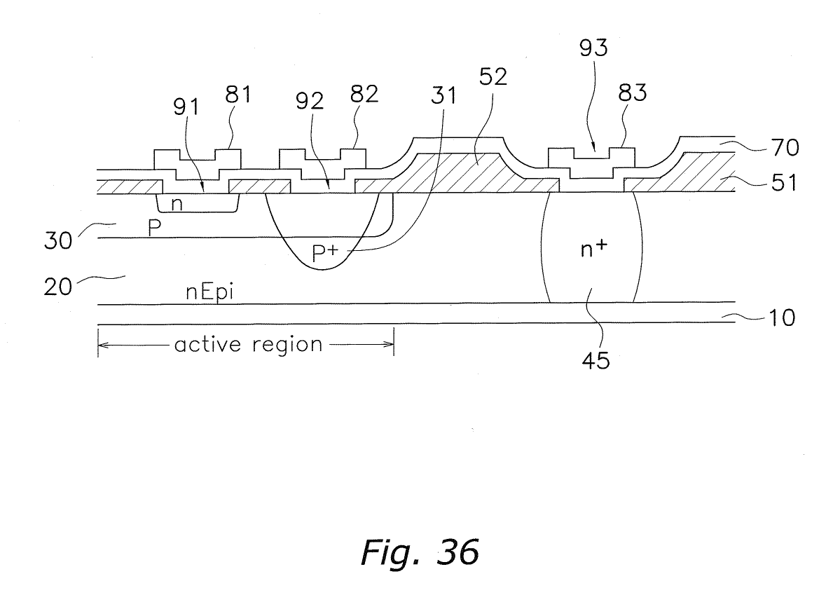

Next, as shown in Fig. 35, a metal layer 80 comprised of Al or AlSi is laminated thereon, and by etching the metal layer 80, the emitter electrode 81, the base electrode 82, and the collector electrode 83 are formed in the positions shown in Fig. 36. Furthermore, as shown in Fig. 27, by using the emitter electrode 81, the base electrode 82, and the collector electrode 83 as a mask and etching the contact layer 70, the emitter electrode 81, base electrode 82 and collector electrode 83 will have the same pattern as the emitter contact layer 71, the base contact layer 72, and the collector contact layer 73.

C. Effects

In the bipolar transistor according to the present embodiment, the masks needed for etching can be reduced because the emitter electrode 81, the base electrode 82, and the collector electrode 83 are used as masks during the etching of the contact layer 70.

In addition, the emitter electrode 81, base electrode 82, and collector electrode 83 and the emitter contact layer 71, the base contact layer 72, and the collector contact layer 73 can be self aligned because the emitter electrode 81, base electrode 82, and collector electrode 83 are used as masks, and because the emitter electrode 81, base electrode 82, and collector electrode 83 will have the same pattern as the emitter contact layer 71, the base contact layer 72, and the collector contact layer 73. Thus, an alignment margin is not needed, the distance between the emitter electrode 81 and base electrode 82 can be shortened in order to reduce the resistance between both electrodes, and the high frequency characteristics of the bipolar transistor can be improved.

In addition, the distance between the base diffusion region 31 and the emitter region 40 can be shortened because the p-type dopant is implanted at a high density from not only above the thermal oxide film 50 but also from above the contact layer 70. Thus, the resistance between the emitter electrode 81 and base electrode 82 can be reduced even further, and the high frequency characteristics of the bipolar transistor can be improved.

Moreover, because the step of annealing the CVD oxide film has been eliminated, the deep diffusion of the dopant inside the base region 30 that occurs due to the heat used in annealing can be prevented, and it thus becomes possible to form a thin base region 30. It therefore becomes easier for the carriers to travel from the emitter region 40 to the collector region 20, and the bipolar transistor can thus be driven at a high frequency.

Furthermore, the field thermal oxide film 52 is formed to be thicker than the active thermal oxide film 51, and thus an increase in the capacitance of the pad electrode used for relaying signals from to the base electrode 82 and the emitter electrode 81 can be prevented.

Moreover, a voltage can be applied from the surface of the semiconductor 10 via the collector electrode 83 provided on the surface thereof because the collector wall region 45 is formed in the collector region 20. Thus, wires are not needed when using face down packaging.

Furthermore, the connection resistance from the bottom portion of the semiconductor substrate 10 to the surface thereof can be reduced by forming the collection wall regions 45.

This application claims priority to Japanese Patent Application Nos. 2002-002164 and 2002-002165. The entire disclosures of Japanese Patent Application Nos. 2002-002164 and 2002-002165 are hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing description of the embodiments according to the present invention are provided for illustration only, and not for the purpose of limiting the invention as defined by the appended claims and their equivalents.

Claims

1. A bipolar transistor formed on top of a semiconductor substrate, comprising:
a first region of a first conductivity type formed on top of the semiconductor substrate;
a second region of a second conductivity type formed on a surface of the first region;
a third region of the first conductivity type formed on a surface of the second region;
a thermal oxide film having a first hole therein that exposes the third region and a second hole therein that exposes the second region;
a first electrode that applies a voltage to the third region through the first hole;
a first contact layer of the first conductivity type formed in between the first electrode and the third region;
a second electrode that applies a voltage to the second region through the second hole; and
a third electrode that applies a voltage to the first region.

2. The bipolar transistor set forth in claim 1, wherein the third electrode is formed on the bottom surface of the semiconductor substrate.

3. The bipolar transistor set forth in claim 1, further comprising:
a third hole formed in the thermal oxide film that exposes the first region; and
wherein the third electrode applies a voltage to the first region through the third hole.

4. The bipolar transistor set forth in claim 1, further comprising a second contact layer of the second conductivity type formed in between the second electrode and the second region.

5. The bipolar transistor set forth in claim 1, further comprising a third contact layer of the first conductivity type formed in between the third electrode and the first region.

6. The bipolar transistor set forth in claim 1, wherein the thermal oxide film is formed to have an active region that is thinner than any other region thereof.

7. A method of manufacturing a bipolar transistor on top of a semiconductor substrate, comprising the steps of:
forming a first region of a first conductivity type on top of the semiconductor substrate;
forming a second region of a second conductivity type on a surface of the first region;
forming a third region of the first conductivity type on a surface of the second region;
forming a thermal oxide film on top of the first, second and third regions;
forming a first hole in the thermal oxide film that exposes the third region and forming a second hole in the thermal oxide film that exposes the second region;
forming a first contact layer of the first conductivity type in the third region through the first hole;
forming a first electrode that applies a voltage to the third region on the surface of the first contact layer;
forming a second electrode that applies a voltage to the second region through the second hole; and
forming a third electrode that applies a voltage to the first region.

8. The bipolar transistor manufacturing method set forth in claim 7, wherein the third electrode is formed on the bottom surface of the semiconductor substrate during the third electrode formation step.

9. The bipolar transistor manufacturing method set forth in claim 7, wherein the step of forming holes in the thermal oxide film further includes a step of forming a third hole in the thermal oxide film that exposes the first region; and
wherein in the third electrode formation step, the third electrode is formed to be in electrical contact with the first region through the third hole.

10. The bipolar transistor manufacturing method set forth in claim 7, wherein the thermal oxide film formed during the thermal oxide formation step has an active region that is thinner than any other region thereof.

11. The bipolar transistor manufacturing method set forth in claim 7, wherein the first and second electrodes formed during the first and second electrode formation steps are composed of Al or AlSi.

12. The bipolar transistor manufacturing method set forth in claim 11, wherein the steps of forming the first and second electrodes from Al or AlSi are further comprised of the steps of:
etching the first and second electrodes with a mixed gas composed of Cl₂ and 20 to 40 wt% of BCl₃, SiCl₄, or BBr₃, wherein the selection ratio between the Al and a resist film is 1.5 to 2.5; and
removing any Al or AlSi residue therefrom with a mixed gas composed of Cl₂ and 5 to 20 wt% of BCl₃, SiCl₄, or BBr₃, wherein the selection ratio between the Al and a resist film is 2 to 3, and the selection ratio between the Al and the thermal oxide film is 20 to 100.

13. A method of manufacturing a bipolar transistor on top of a semiconductor substrate, comprising the steps of:
forming a first region of a first conductivity type on top of the semiconductor substrate;
forming a second region of a second conductivity type on a surface of the first region;
forming a third region of the first conductivity type on a surface of the second region;
forming a thermal oxide film on top of the first, second and third regions;
forming a first hole in the thermal oxide film that exposes the third region and forming a second hole in the thermal oxide film that exposes the second region;
sequentially forming a contact layer and an electrode layer after forming the first and second holes in the thermal oxide film;
etching the electrode layer to form a first electrode in the first hole and a second electrode in the second hole;
using the first and second electrode as a mask and etching the contact layer; and
forming a third electrode that applies a voltage to the first region.

14. The bipolar transistor manufacturing method set forth in claim 13, wherein the third electrode is formed on the bottom surface of the semiconductor substrate during the third electrode formation step.

15. The bipolar transistor manufacturing method set forth in claim 13, wherein the hole formation step further includes the step of forming a third hole in the thermal oxide film that exposes the first region; and
the third electrode is formed to be in electrical contact with the first region through the third hole in the third electrode formation step.

16. The bipolar transistor manufacturing method set forth in claim 13, wherein the step of forming the second region further comprises:
a first implantation step in which dopant of the second conductivity type is implanted from above the thermal oxide film into the first region; and
a second implantation step in which dopant of the second conductivity type is implanted from above the contact layer into the same position in which the dopant of the first implantation step was implanted into the first region.

17. The bipolar transistor manufacturing method set forth in claim 13, wherein the thermal oxide film formed in the thermal oxide film formation step has an active region that is thinner than any other region thereof.

18. The bipolar transistor manufacturing method set forth in claim 13, wherein the first and second electrodes formed during the electrode formation step are composed of Al or AlSi.
